(19) United States
(12) Patent Application Publication
(10) Pub. No.: US 2026/0369640 A1
(43) Pub. Date: Nov. 19, 2026

(54) METHOD FOR ASCERTAINING AN ELECTRICAL RESISTANCE OF AT LEAST ONE FUEL CELL, FUEL CELL SYSTEM, AND VEHICLE

(71) Applicant: Robert Bosch GmbH, Stuttgart (DE)

(72) Inventors: Christophe Gerling, Filderstadt (DE); Michael Giuseppe Marino, Linz (AT)

(21) Appl. No.: 19/102,128

(22) PCT Filed: Aug. 4, 2023
(86) PCT No.: PCT/EP2023/071628

§ 371 Date: Feb. 7, 2025

(30) Foreign Application Priority Data
Aug. 8, 2022 (DE) 10 2022 208 221.4

(51) Int. Cl. H01M 8/04992; H01M 8/04537; H01M 8/10; H01M 8/241

(52) U.S. Cl. CPC H01M 8/04992; H01M 8/04559; H01M 8/04649; H01M 8/241; H01M 2008/1095; H01M 2250/20

(57) ABSTRACT

The invention relates to a method for ascertaining an electrical resistance of at least one fuel cell of a fuel cell stack (10). The method has the steps of providing (320) a fuel cell system (100) with the fuel cell stack (10), wherein a cathode gas on the cathode side of the at least one fuel cell of the fuel cell stack (10) is free of an oxidizing agent. Furthermore, the method comprises a step of applying (360) at least one such electrical test signal to at least one fuel cell, such that anode gas protons at least in the at least one fuel cell are moved from the anode side to the cathode side of the at least one fuel cell. Furthermore the method comprises a step of detecting (380) at least one signal response of the at least one fuel cell in response to the at least one applied electrical test signal. Furthermore, the method comprises a step of ascertaining (400) the electrical resistance of the at least one fuel cell of the fuel cell stack (10) of the fuel cell system (100) on the basis of the at least one applied electrical test signal and the at least one detected signal response.

### BACKGROUND

Fuel cells are electrochemical energy converters in which, for example, hydrogen (H2) and oxygen (O2) are converted into water (H2O), electrical energy and heat.

The porous electrodes of a polymer electrolyte membrane fuel cell, commonly referred to as a catalyst layer, may comprise platinum particles (catalyst) supported on larger carbon particles. This carbon phase provides electron and heat transport. The layer can also be permeated with ionomer to ensure proton conductivity. The electrochemical reaction requires a triple phase boundary, which is formed when platinum, ionomer and reactant come together. The membrane is located in the center of the construction and may primarily comprise ionomers. The function of this membrane is to transport hydrogen protons from the anode electrode to the cathode electrode with as little loss as possible, but also to separate both gas spaces from one another (gas tightness) and to act as an electrical insulator. The proton conductivity of a given membrane depends primarily on two parameters: temperature and water content, the latter being very strongly coupled to the fuel cell current and the gas channel moisture.

Since membrane resistance is an important indicator of fuel cell performance, it is important to monitor it during operation. If the resistance is too high, overall performance may be poor and there is a risk of drying. Dry conditions may also be bad for the service life, as a membrane becomes warmer in a dry state than in a moistened state at a given current. Very wet conditions may indicate possible flooding effects of the electrodes in extreme situations. It is known to determine the membrane resistance by means of AC current or AC voltage measurement, wherein an AC signal is superimposed on the DC state during operation and the response of the system is recorded. The electrochemical impedance spectroscopy (EIS) may be determined via amplitude ratios and phase shift. Either a fixed frequency can be continuously superimposed and measured (High Frequency Resistance, HFR), or a complete electrochemical impedance spectrum can be measured in given situations, wherein the frequencies are mostly sampled from the kilohertz range to the millihertz range, which can be very time-consuming.

A further known method is the so-called “current interruption” method. In this complex method, the load is interrupted and the response of the fuel cell is sampled at high frequency. The Ohm's resistance is then determined via mathematical analyses.

### SUMMARY

The present invention discloses a method, a fuel cell system and a vehicle according to the disclosure.

In this context, features and details described in connection with the method according to the invention clearly also apply in connection with the fuel cell system according to the invention as well as the vehicle according to the invention, and respectively vice versa so that, with respect to the disclosure, mutual reference to the individual aspects of the invention is or can always be made.

According to a first aspect, the present invention discloses a method for ascertaining an electrical resistance of at least one fuel cell of a fuel cell stack of a fuel cell system, wherein each fuel cell of a plurality of fuel cells of the fuel cell stack has an anode side, a cathode side, and a membrane. The method comprises a first step of providing the fuel cell system with the fuel cell stack, wherein a cathode gas on the cathode side of the at least one fuel cell of the fuel cell stack is free of an oxidizing agent of the cathode gas or substantially free of an oxidizing agent of the cathode gas. In addition, the method comprises a step of applying at least one such electrical test signal to at least one fuel cell of the plurality of fuel cells of the fuel cell stack provided, such that anode gas protons at least in the at least one fuel cell are moved from the anode side via the membrane of the at least one fuel cell to the cathode side of the at least one fuel cell. In addition, the method comprises a step of detecting at least one signal response of the at least one fuel cell in response to the at least one applied electrical test signal. In addition, the method comprises a step of ascertaining the electrical resistance of the at least one fuel cell of the fuel cell stack of the fuel cell system on the basis of the at least one applied electrical test signal and the at least one detected signal response.

The method steps described above and below can be performed individually, together, once, several times, in parallel, and/or consecutively in any order, provided that doing so is technically feasible.

In particular, the above steps may be repeated e.g., at least once during a journey of a vehicle, in order to repeatedly determine an electrical resistance of the at least one fuel cell of the fuel cell stack or a (total) electrical resistance of the fuel cell stack of the fuel cell system on the basis of the at least one applied electrical test signal and the at least one detected signal response in each case. Thus, an electrical resistance of the fuel cell, in particular a membrane resistance, can be monitored over time. By monitoring the membrane resistance, a fuel cell performance can be inferred.

In particular, the fuel cell stack comprises bipolar plates and membrane electrode units, wherein the bipolar plates and membrane electrode units are alternately stacked one on top of the other. The fuel cell stack may have an end plate at each end of the fuel cell stack. In particular, a membrane electrode unit comprises a membrane having a first membrane side and a second membrane side opposite the first membrane side, an anode electrode arranged on the first membrane side of the membrane, a cathode electrode arranged on the second membrane side of the membrane, a cathode electrode catalyst layer arranged on the anode electrode and/or a cathode electrode catalyst layer arranged on the cathode electrode and/or a cathode gas diffusion layer arranged on the cathode electrode, an anode electrode catalyst layer arranged at the anode electrode and/or a cathode electrode catalyst layer arranged at the cathode electrode and/or a cathode gas diffusion layer at least for distributing a cathode gas to the cathode electrode and/or an anode gas diffusion layer at least for distributing an anode gas to the anode electrode. Furthermore, in particular, the fuel cell stack is a polymer electrolyte membrane fuel cell stack.

Features and/or details and/or embodiments and/or advantages which are expressed with respect to the at least one fuel cell of the fuel cell stack or a fuel cell of the fuel cell stack may also be transferred to the other fuel cells of the fuel cell stack, and vice versa.

In particular, an anode side of the at least one fuel cell comprises an anode plate half of a bipolar plate of the fuel cell stack, an anode electrode, and an anode electrode catalyst layer arranged on the anode electrode. In addition, the anode side may still comprise an anode gas diffusion layer.

In particular, a cathode side of the at least one fuel cell comprises a cathode plate half of a bipolar plate of the fuel cell stack, a cathode electrode, and a cathode electrode catalyst layer arranged on the cathode electrode. In addition, the cathode side may still comprise a cathode gas diffusion layer.

In particular, the electrical resistance of the at least one fuel cell comprises at least one (electrical or electronic) contact resistance, for example, an (electrical or electronic) contact resistance between two components of the fuel cell, such as a bipolar plate and a gas diffusion layer, and/or at least one (electrical or electronic) layer resistance, e.g. a layer resistance of a gas diffusion layer, and/or at least one kinetic resistance, for example, a resistance of the oxygen kinetics or the hydrogen kinetics, and/or a membrane resistance. The membrane resistance may also be understood as a protonic ohmic resistance. Contact resistances and/or layer resistances may remain nearly constant during operation of the fuel cell system, so that it may be sufficient to determine these once and then always subtract them from the determined electrical resistance in order to determine the membrane resistance. For example, a layer resistance of an anode gas diffusion layer can occur before the fuel cell stack is assembled, i.e. on the anode gas diffusion layer as a single part. The layer resistance determined in this way can be stored in a ascertainment unit of a fuel cell system according to the invention.

For example, the fuel cell system with the fuel cell stack may, for example, be provided on a vehicle, for example, a fuel cell vehicle.

The at least one applied electrical test signal may be a voltage signal, wherein in response to the voltage signal (as the at least one applied electrical test signal), a current signal is detected as the at least one signal response. The voltage signal as an electrical test signal may be detected, for example, by means of a voltage measuring unit, for example, a voltmeter, and/or the current signal may be detected as the at least one signal response by means of a current measuring unit, for example, an ammeter. Alternatively or additionally, it is also contemplated that the at least one applied electrical test signal is a current signal, wherein in response to the current signal (as the at least one applied electrical test signal), a voltage signal is detected as the at least one signal response. The current signal as an electrical test signal may be detected, for example, by means of a current measuring unit, for example an ammeter, and/or the voltage signal may be detected as the at least one signal response by means of a voltage measuring unit, for example, a voltmeter. In particular, a detection unit of a fuel cell system according to the present invention comprises the current measurement unit and/or the voltage measurement unit. Advantageously, pre-existing components are used as the voltage measurement unit and/or current measurement unit for operation or monitoring of the fuel cell system.

In particular, such an electrical test signal is applied to the at least one fuel cell of the plurality of fuel cells, which at least temporarily has a first signal level and at least temporarily has a second signal level which is different from the first signal level, wherein both for the first signal level and for the second signal level (respectively), the anode gas protons at least in the at least one fuel cell are moved from the anode side via the membrane of the at least one fuel cell to the cathode side of the at least one fuel cell. The movement of the anode gas protons may also be understood as proton pumping. In particular, such an electrical test signal is applied to the at least one fuel cell of the plurality of fuel cells, such that the fuel cell stack at least temporarily has a negative fuel cell stack potential difference, wherein in particular the value of the negative fuel cell stack potential difference changes at least once over time, in particular significantly changes. For example, a step-shaped current signal may be applied as the at least one electrical test signal, wherein, for example, 5 A(ampere) and, for example, 10 A(mpere) are temporarily applied to the at least one fuel cell. A step-shaped or substantially step-shaped voltage signal may be detected as the signal response of the at least one fuel cell in response to a step-shaped current signal. The electrical resistance of the fuel cell can be ascertained from the step-shaped current signal as the at least one (applied) electrical test signal and the step-shaped voltage signal as the at least one signal response.

Ascertaining the electrical resistance of the at least one fuel cell of the fuel cell stack of the fuel cell system on the basis of the at least one applied electrical test signal and the at least one detected signal response is carried out in particular with the aid of Ohm's law, for example by an ascertainment unit of a fuel cell system according to the invention.

Because the fuel cell system with the fuel cell stack is free of the oxidizing agent of the cathode gas or substantially free of the oxidizing agent of the cathode gas, the number of reaction partners is kept particularly low and an electrical resistance of the at least one fuel cell of the fuel cell stack can be ascertained in a particularly simple manner and thus monitoring of the fuel cell stack can also be carried out particularly simply and/or inexpensively and/or quickly. The cathode gas may, for example, be air, wherein the oxygen in the air constitutes the oxidizing agent of the cathode gas. Advantageously, a cathode catalyst layer can also be additionally cleaned by ascertaining the electrical resistance according to the invention.

It may be advantageous to provide at least the fuel cell stack of the fuel cell system in a defined state in a method according to the invention. Thus, ascertaining the electrical resistance of the at least one fuel cell of the fuel cell stack or of the fuel cell stack can occur particularly precisely and the electrical resistance of the at least one fuel cell or of the fuel cell stack, in particular a membrane resistance, can be monitored particularly advantageously over time. For example, the fuel cell stack may have been operated for a definable period of time and/or a membrane of the fuel cell stack may have a definable minimum moisture and/or the fuel cell stack may have a definable minimum temperature.

It may be advantageous if, in a method according to the invention, a cathode gas supply of the fuel cell system for supplying cathode gas to the cathode sides of the plurality of fuel cells is fluidly interrupted, and in particular the fuel cell stack is at least temporarily electrically loaded in order to bring the cathode gas on the cathode side of the at least one fuel cell of the fuel cell stack free of the oxidizing agent of the cathode gas or substantially free of the oxidizing agent of the cathode gas. Thus, in a particularly simple manner, the cathode gas on the cathode side of the at least one fuel cell of the fuel cell stack may be brought free of the oxidizing agent of the cathode gas or substantially free of the oxidizing agent of the cathode gas. Previously, in an additional step, the power of the fuel cell stack may be reduced. Fluidly interrupting the cathode gas supply of the fuel cell system for supplying cathode gas to the cathode sides of the plurality of fuel cells may occur by closing a valve at the cathode input of the fuel cell stack. A current tap may also be used to force a fuel cell reaction between the oxidizing agent of the cathode gas and the reducing agent of the anode gas, such that the oxidizing agent, e.g. oxygen, of the cathode gas is completely or substantially completely reduced and the cell potential is brought to zero or substantially to zero. Because the oxidizing agent has been consumed or is substantially consumed it may be detected, for example, by detecting and evaluating a fuel cell stack potential difference and/or by detecting and evaluating a current through the fuel cell stack. The reducing agent, e.g. hydrogen, may also flow on a respective anode side of the plurality of fuel cells, wherein water and nitrogen or substantially water and nitrogen (with air as the cathode gas) are present in particular on the respective cathode side of the plurality of fuel cells.

It may be advantageous if, in a method according to the invention, at least temporarily a step-shaped signal and/or at least temporarily a ramp-shaped signal and/or at least temporarily a jump-shaped signal and/or at least temporarily a discrete signal is applied as the at least one test signal. In particular, the at least temporarily step-shaped signal and/or the at least temporarily ramp-shaped signal and/or the at least temporarily jump-shaped signal and/or the at least temporarily discrete signal have at least a first signal level, and a second signal level which is different from the first signal level. It is further contemplated that different electrical test signals may be applied in succession.

It may be advantageous if, in a method according to the invention, a current signal with increasing current is applied as the at least one electrical test signal, wherein a voltage is detected as the at least one signal response. Thus, the electrical resistance of the at least one fuel cell may be ascertained in a particularly simple manner. For example, in the case of a step-shaped signal, at least a first signal level, and a second signal level which is different from the first signal level, may be applied as the at least one electrical test signal.

It may be advantageous if, in a method according to the invention, the at least one electrical test signal is applied to at least two fuel cells of the plurality of fuel cells of the fuel cell stack provided, such that anode gas protons in the at least two fuel cells are moved from a respective anode side via the respective membrane of the respective fuel cell to the respective cathode side of the respective fuel cell of the at least two fuel cells. Thus, the electrical resistance can be ascertained from a plurality of fuel cells of the fuel cell stack and monitoring of the fuel cell stack can occur particularly accurately. It may be advantageous if, in a method according to the invention, an electrical resistance is ascertained for a respective fuel cell of the at least two fuel cells on the basis of the at least one applied electrical test signal and a respective detected signal response, or that a total electrical resistance is ascertained for the at least two fuel cells on the basis of the at least one applied electrical test signal and the detected signal response. If an electrical resistance is ascertained for the respective fuel cell of the at least two fuel cells on the basis of the at least one applied electrical test signal and a respective detected signal response, the respective fuel cell of the at least two fuel cells can be monitored and, for example, a defective fuel cell can be localized particularly easily. If the total electrical resistance for the at least two fuel cells is ascertained on the basis of the at least one applied electrical test signal and the detected signal response, it is particularly easy and requires little effort to at least monitor whether there is a faulty membrane in the fuel cell stack, for example. For example, the electrical test signal may be applied to two current collector plates of the fuel cell stack to ascertain the total electrical resistance.

It may be advantageous if, in a method according to the invention, a membrane resistance of the membrane of the at least one fuel cell of the fuel cell stack is ascertained on the basis of the at least one applied electrical test signal, the at least one detected signal response and additionally on at least one layer resistance and/or at least one contact resistance and/or at least one kinetic resistance of at least the fuel cell stack, in particular the at least one fuel cell. In particular, the at least one layer resistance and/or the at least one contact resistance and/or the at least one kinetic resistance of at least the fuel cell stack, in particular the at least one fuel cell, can be ascertained or measured in advance and stored in each case in an ascertainment unit of a fuel cell system according to the invention. To ascertain the membrane resistance, the at least one layer resistance and/or the at least one contact resistance and/or the at least one kinetic resistance may be subtracted.

It may be advantageous if, in a method according to the present invention, the method for ascertaining the electrical resistance is performed when a reduction of an electrical power demand to the fuel cell stack is detected and/or anticipated. Thus, ascertaining the electrical resistance can also be carried out, for example, during a journey of a vehicle, for example when stationary at traffic lights. Alternatively or additionally, the method for ascertaining the electrical resistance may be carried out when it is detected that an electrical power demand to the fuel cell stack can be buffered by a buffer unit of the fuel cell system. The buffer unit may be a battery, for example a vehicle battery. The expression “the method for ascertaining the electrical resistance is performed” is intended to express that a starting condition for the steps of providing the fuel cell stack, wherein a cathode gas on the cathode side of the at least one fuel cell of the fuel cell stack is free of an oxidizing agent of the cathode gas or substantially free of an oxidizing agent of the cathode gas, and applying the electrical test signal, and detecting the at least one signal response, and ascertaining the electrical resistance may be that a reduction of an electrical power demand to the fuel cell stack is detected and/or anticipated, and/or that an electrical power demand to the fuel cell stack can be buffered by a buffer unit of the fuel cell system.

According to a second aspect, the present invention relates to a fuel cell system. The fuel cell system comprises a fuel cell stack having a plurality of fuel cells, each fuel cell of the plurality of fuel cells having an anode side, a cathode side and a membrane. The fuel cell system further comprises a control unit for controlling the fuel cell system with the fuel cell stack, wherein the control unit is configured to bring a cathode gas on the cathode side of the at least one fuel cell of the fuel cell stack free of an oxidizing agent of the cathode gas or substantially free of an oxidizing agent of the cathode gas. The fuel cell system comprises a test signal generator unit for applying at least one such electrical test signal to the at least one fuel cell of the plurality of fuel cells, such that anode gas protons at least in the at least one fuel cell can be moved from the anode side via the membrane of the at least one fuel cell to the cathode side of the at least one fuel cell. In particular, the test signal generator unit is further configured to apply such a test signal, such that the at least one electrical test signal at least temporarily has a first signal level and at least temporarily a second signal level which is different from the first signal level, to move anode gas protons at least in the at least one fuel cell from the anode side via the membrane of the at least one fuel cell to the cathode side of the at least one fuel cell. The fuel cell system further comprises a detection unit for detecting at least one signal response of the at least one fuel cell in response to the at least one applied electrical test signal. The fuel cell system also comprises an ascertainment unit for ascertaining at least one electrical resistance of the at least one fuel cell, in particular a membrane resistance of the membrane of the at least one fuel cell, of the fuel cell stack of the fuel cell system on the basis of the at least one applied electrical test signal and the at least one detected signal response.

It may be advantageous if a fuel cell system according to the invention is configured to perform a method according to the invention.

The method according to the second aspect of the invention thus has the same advantages as have already been described for the fuel cell system according to the first aspect of the invention.

According to a third aspect, the present invention relates to a vehicle, in particular a motor vehicle, having a mounting interface, wherein a fuel cell system is configured according to the invention and is arranged with a counter-mounting interface on the mounting interface of the vehicle.

The vehicle is in particular a motor vehicle, e.g. a passenger car or a truck or a motorcycle.

The vehicle according to the third aspect of the invention thus has the same advantages as have already been described for the method according to the first aspect of the invention or the fuel cell system according to the second aspect of the invention.

Further measures improving the invention arise from the following description of a few exemplary embodiments of the invention, which are schematically represented in the figures. All of the features and/or advantages arising from the claims, description, or drawings, including structural details, spatial arrangements, and method steps, can be essential to the invention both by themselves and in the various combinations. It should be noted that the figures have only a descriptive character and are not intended to limit the invention in any way.

### BRIEF DESCRIPTION OF THE DRAWINGS

Schematically shown are:

FIG. 1 a fuel cell system,

FIG. 2 a vehicle, and

FIG. 3 a method.

In the following figures, identical reference numbers are used for identical technical features, even in different exemplary embodiments.

### DETAILED DESCRIPTION

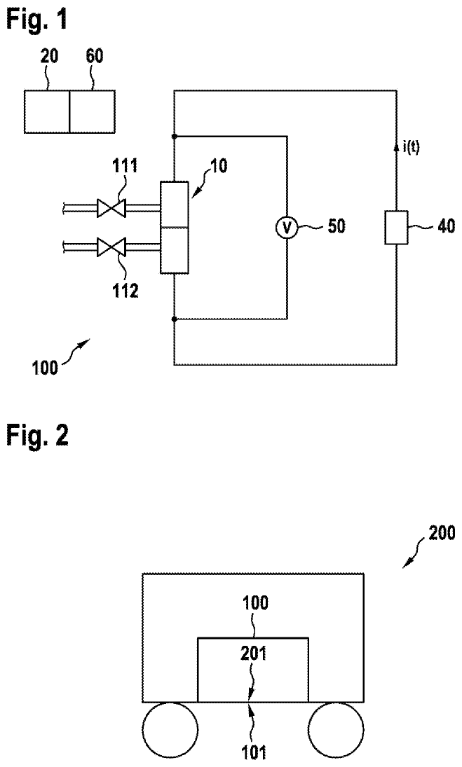

FIG. 1 schematically discloses a fuel cell system 100 for a vehicle 200.

The fuel cell system 100 comprises a fuel cell stack 10 having a plurality of fuel cells, each fuel cell of the plurality of fuel cells having an anode side, a cathode side and a membrane. The fuel cell system 100 further comprises a control unit 20 for controlling the fuel cell system 100 with the fuel cell stack 10, wherein the control unit 20 is configured to bring a cathode gas on the cathode side of the at least one fuel cell of the fuel cell stack 10 free of an oxidizing agent of the cathode gas or substantially free of an oxidizing agent of the cathode gas, for example by fluidly interrupting the cathode gas supply. Fluidly interrupting the cathode gas supply may be accomplished by closing a valve 111 in the cathode gas supply. In addition to the cathode gas supply, the fuel cell stack 10 comprises an anode gas supply with a valve 112. Furthermore, the fuel cell system 100 comprises a test signal generator unit 40 for applying at least one such electrical test signal to the at least one fuel cell of the plurality of fuel cells, such that anode gas protons at least in the at least one fuel cell can be moved from the anode side via the membrane of the at least one fuel cell to the cathode side of the at least one fuel cell. Furthermore, the fuel cell system 100 comprises a detection unit 50 for detecting at least one signal response of the at least one fuel cell in response to the at least one applied electrical test signal. Furthermore, the fuel cell system 100 comprises an ascertainment unit 60 for ascertaining at least one electrical resistance of the at least one fuel cell, in particular a membrane resistance of the membrane of the at least one fuel cell, of the fuel cell stack 10 of the fuel cell system 100 on the basis of the at least one applied electrical test signal and the at least one detected signal response.

FIG. 2 schematically discloses a vehicle 200, in particular a motor vehicle, having a mounting interface 201, wherein a fuel cell system 100, as described in particular with respect to FIG. 1, having a counter-mounting interface 101 is arranged on the mounting interface 201 of the vehicle 200.

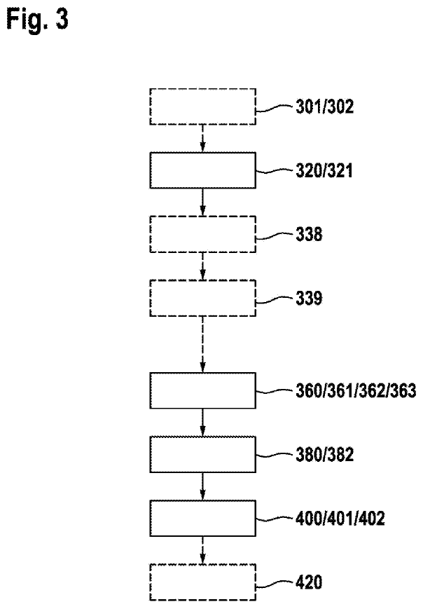

FIG. 3 discloses a method for ascertaining an electrical resistance of at least one fuel cell of a fuel cell stack 10 of a fuel cell system 10, as described for example with respect to FIG. 1, wherein each fuel cell of a plurality of fuel cells of the fuel cell stack 10 comprises an anode side, a cathode side, and a membrane. The method comprises a step of providing 320 the fuel cell system 100 with the fuel cell stack 10, wherein a cathode gas on the cathode side of the at least one fuel cell of the fuel cell stack 10 is free of an oxidizing agent of the cathode gas or substantially free of an oxidizing agent of the cathode gas. It may additionally be contemplated, i.e., optionally, in the method that at least the fuel cell stack 10 of the fuel cell system 100 is provided in a defined state 321. Furthermore, the method comprises a step of applying 360 at least one such electrical test signal, e.g., applying 362 a current signal with increasing current, to at least one fuel cell of the plurality of fuel cells of the fuel cell stack 10 provided, such that anode gas protons at least in the at least one fuel cell are moved from the anode side via the membrane of the at least one fuel cell to the cathode side of the at least one fuel cell. It may additionally be contemplated as an additional, i.e., optional, step in the method that at least temporarily a step-shaped signal and/or at least temporarily a ramp-shaped signal and/or at least temporarily a jump-shaped signal and/or at least temporarily a discrete signal is applied 361 as the at least one test signal. Furthermore, the method comprises a step of detecting 380 at least one signal response, for example detecting a voltage 382, of the at least one fuel cell in response to the at least one applied electrical test signal. Furthermore, the method comprises a step of ascertaining 400 the electrical resistance of the at least one fuel cell of the fuel cell stack 10 of the fuel cell system 100 on the basis of the at least one applied electrical test signal and the at least one detected signal response. It may additionally be contemplated as an additional, i.e. optional, step that the method for ascertaining the electrical resistance is performed when a reduction of an electrical power demand to the fuel cell stack is detected and/or anticipated 301 and/or when it is detected 302 that an electrical power demand to the fuel cell stack 10 can be buffered by a buffer unit, for example a battery, of the fuel cell system 100. Detecting or anticipating may be performed, for example, by a control unit of the fuel cell system 100. It may additionally be contemplated as an additional, i.e. optional, step that the at least one electrical test signal is applied 363 to at least two fuel cells of the plurality of fuel cells of the fuel cell stack 10 provided, such that anode gas protons in the at least two fuel cells are moved from a respective anode side via the respective membrane of the respective fuel cell to the respective cathode side of the respective fuel cell of the at least two fuel cells. It may additionally be contemplated as an additional, i.e. optional, step that an electrical resistance is ascertained for a respective fuel cell of the at least two fuel cells on the basis of the at least one applied electrical test signal and a respective detected signal response, or that a total electrical resistance is ascertained 401 for the at least two fuel cells on the basis of the at least one applied electrical test signal and the detected signal response 402. It may additionally be contemplated as an additional, i.e. optional, step that a membrane resistance of the membrane of the at least one fuel cell of the fuel cell stack 10 is ascertained 420 on the basis of the at least one applied electrical test signal, the at least one detected signal response and additionally on at least one layer resistance and/or at least one contact resistance and/or at least one kinetic resistance of at least the fuel cell stack, in particular the at least one fuel cell.

1. A method for determining an electrical resistance of at least one fuel cell of a fuel cell stack (10) of a fuel cell stack system (10), wherein each fuel cell of a plurality of fuel cells of the fuel cell stack (10) has an anode side, a cathode side, and a membrane, the method having the steps of:
providing (320) the fuel cell system (100) with the fuel cell stack (10), wherein a cathode gas on the cathode side of the at least one fuel cell of the fuel cell stack (10) is free of an oxidizing agent of the cathode gas or is substantially free of an oxidizing agent of the cathode gas,
applying (360) at least one such electrical test signal to at least one fuel cell of the plurality of fuel cells of the fuel cell stack (10) provided, such that anode gas protons at least in the at least one fuel cell are moved from the anode side via the membrane of the at least one fuel cell to the cathode side of the at least one fuel cell,
detecting (380) at least one signal response of the at least one fuel cell in response to the at least one applied electrical test signal,
determining (400) the electrical resistance of the at least one fuel cell of the fuel cell stack (10) of the fuel cell system (100) based on the at least one applied electrical test signal and the at least one detected signal response.

2. The method according to claim 1,
wherein
at least the fuel cell stack (10) of the fuel cell system (100) is provided in a defined state (321).

3. The method according to claim 1,
wherein
a cathode gas supply (1) of the fuel cell system (100) for supplying cathode gas to the cathode sides of the plurality of fuel cells is fluidly interrupted (338), to bring the cathode gas on the cathode side of the at least one fuel cell of the fuel cell stack (10) free of the oxidizing agent of the cathode gas or substantially free of the oxidizing agent of the cathode gas.

4. The method according to claim 1,
wherein
at least temporarily a step-shaped signal and/or at least temporarily a ramp-shaped signal and/or at least temporarily a jump-shaped signal and/or at least temporarily a discrete signal is applied (361) as the at least one electrical test signal.

5. The method according to claim 1,
wherein
a current signal with increasing current is applied (362) as the at least one electrical test signal, wherein a voltage is detected (382) as the at least one signal response.

6. The method according to claim 1,
wherein
the at least one electrical test signal is applied (363) to at least two fuel cells of the plurality of fuel cells of the fuel cell stack (10) provided, such that anode gas protons in the at least two fuel cells are moved from a respective anode side via the respective membrane of the respective fuel cell to the respective cathode side of the respective fuel cell of the at least two fuel cells.

7. The method according to claim 6,
wherein
an electrical resistance is determined for a respective fuel cell of the at least two fuel cells on the basis of the at least one applied electrical test signal and a respective detected signal response (401), or that a total electrical resistance is determined (402) for the at least two fuel cells on the basis of the at least one applied electrical test signal and the detected signal response.

8. The method according to claim 1,
wherein
a membrane resistance of the membrane of the at least one fuel cell of the fuel cell stack (10) is determined (420) on the basis of the at least one applied electrical test signal, the at least one detected signal response and additionally on at least one layer resistance and/or at least one contact resistance and/or at least one kinetic resistance of at least the fuel cell stack.

9. The method according to claim 1,
wherein
the method for determining the electrical resistance is performed when a reduction of an electrical power demand to the fuel cell stack is detected and/or anticipated (301)
and/or
the method for determining the electrical resistance is performed when it is detected (302) that an electrical power demand to the fuel cell stack (10) can be buffered by a buffer unit of the fuel cell system (100).

10. A fuel cell system (100) of a motor vehicle (200), wherein the fuel cell system (100) comprises:
a fuel cell stack (10) having a plurality of fuel cells, each fuel cell of the plurality of fuel cells each having an anode side, a cathode side, and a membrane,
a control unit (20) for controlling the fuel cell system (100) with the fuel cell stack (10), wherein the control unit (20) is configured to bring a cathode gas on the cathode side of the at least one fuel cell of the fuel cell stack (10) free of an oxidizing agent of the cathode gas or substantially free of an oxidizing agent of the cathode gas,
a test signal generator unit (40) for applying at least one such electrical test signal to the at least one fuel cell of the plurality of fuel cells, such that anode gas protons at least in the at least one fuel cell can be moved from the anode side via the membrane of the at least one fuel cell to the cathode side of the at least one fuel cell,
a detection unit (50) for detecting at least one signal response of the at least one fuel cell in response to the at least one applied electrical test signal,
an ascertainment unit (60) for determining at least one electrical resistance of the at least one fuel cell, of the fuel cell stack (10) of the fuel cell system (100) on the basis of the at least one applied electrical test signal, and the at least one detected signal response.

11. (canceled)

12. A vehicle (200), having a mounting interface (201), wherein a fuel cell system (100) according to claim 10 having a counter-mounting interface (101) is arranged on the mounting interface (201) of the vehicle (200).
